(19) United States
(12) Patent Application Publication
(10) Pub. No.: US 2013/0141179 A1
(43) Pub. Date: Jun. 6, 2013

(54) OSCILLATING DEVICE FOR FREQUENCY DETECTION, ULTRASONIC TRANSCEIVER SYSTEM AND FREQUENCY DETECTION METHOD THEREOF

(71) Applicants: Chern-Lin CHEN, Taipei (TW); Hsang-Wei Hwang, Taipei (TW)

(72) Inventors: Chern-Lin CHEN, Taipei (TW); Hsang-Wei Hwang, Taipei (TW)

(73) Assignee: National Taiwan University, Taipei City (TW)

(21) Appl. No.: 13/414,805

(22) Filed: Mar. 8, 2012

(30) Foreign Application Priority Data
Dec. 6, 2011 (TW) 100144793

(51) Int. Cl. H03B 5/32

(52) U.S. Cl. 331/158

(57) ABSTRACT

The present invention discloses an oscillating device for frequency detection, an ultrasonic transceiver system and a frequency detection method thereof. The oscillating device for frequency detection, which is applicable for detecting a transducer having a lowest impedance frequency and a highest impedance frequency, comprises an oscillating circuit. The oscillating circuit has a loop gain whose maximum value occurs at the lowest impedance frequency of the transducer and whose minimum value occurs at the highest impedance frequency of the transducer, wherein a difference of a phase of the loop gain and an impedance phase of the transducer is zero between the lowest impedance frequency and the highest impedance frequency, and the loop gain is of a value greater than 1 at a frequency where the phase difference is zero.

### BACKGROUND OF THE INVENTION

1. Field of the Invention

The present invention relates to a device for frequency detection and a method thereof, and more particularly, to an oscillating device for frequency detection, an ultrasonic transceiver system and a frequency detection method thereof that exploit the impedance of an ultrasonic transducer to find the best transmission frequency.

2. Description of the Prior Art

The best reception and transmission frequencies for a current ultrasonic transducer may vary with factors such as changes in external environment (e.g. temperature, moisture, etc.) or process variation. As a result, the best reception and transmission frequencies may be different from the actual reception and transmission frequencies, energy may be wasted and the effective reception distance may be reduced.

Currently, the detection of best reception and transmission points for an ultrasonic transducer is performed through frequency scanning technique. Such technique involves repeatedly transmitting and receiving ultrasonic waves in different frequencies (from low to high) and memorizing the ultrasonic wave receiving condition. Then the best working frequencies for the ultrasonic transducer will be selected as the reception and transmission frequencies. However, the repeated reception and transmission require more power consumption and the frequency scanning operation needs to be performed several times to define the best reception and transmission frequencies. That is, it takes more power and longer time for frequency selection and calibration. Such technique takes longer time and lacks efficiency, thus it is not a desirable solution.

Therefore, a need exists in the art for an oscillating device for frequency detection, an ultrasonic transceiver system and a frequency detection method thereof capable of finding the best transmission frequency.

### SUMMARY OF THE INVENTION

In view of the above problems, the present invention aims to provide an oscillating device for frequency detection, an ultrasonic transceiver system and a frequency detection method thereof so as to solve the problems that the reception and transmission efficiencies of the ultrasonic transducer are unsatisfactory due to the variation of best reception and transmission frequencies with factors such as temperature, environment or manufacturing process, and that the effective detection distance is reduced.

To fulfill the aforementioned aim, the present invention provides an oscillating device for frequency detection for detecting a transducer having a lowest impedance frequency and a highest impedance frequency, comprising: an oscillating circuit having a loop gain whose maximum value occurs at the lowest impedance frequency of the transducer and whose minimum value occurs at the highest impedance frequency of the transducer, wherein a difference of a phase of the loop gain and an impedance phase of the transducer is zero between the lowest impedance frequency and the highest impedance frequency, and the loop gain is of a value greater than 1 at a frequency where the phase difference is 0.

To fulfill the aforementioned aim, the present invention further provides a frequency detection method for detecting an operating frequency of a transducer having a lowest impedance frequency and a highest impedance frequency comprising: providing an oscillating circuit having a loop gain and an output end, a maximum value of the loop gain occurring at the lowest impedance frequency of the transducer, a minimum value of the loop gain occurring at the highest impedance frequency of the transducer, a difference of a phase of the loop gain and an impedance phase of the transducer being zero between the lowest impedance frequency and the highest impedance frequency and the loop gain being of a value greater than 1; connecting the transducer to the output end of the oscillating circuit; and measuring an oscillating frequency of the oscillating circuit, the oscillating frequency being the operating frequency of the transducer.

Preferably, the transducer is an ultrasonic transducer and the lowest impedance frequency is the best transmission frequency for the ultrasonic transducer.

Preferably, the ultrasonic transducer has two zeros at the lowest impedance frequency.

Preferably, the loop gain of the oscillating circuit has two poles at the lowest impedance frequency.

Preferably, the transducer is an ultrasonic transducer and the highest impedance frequency is the best reception frequency for the ultrasonic transducer.

Preferably, the ultrasonic transducer has two poles at the highest impedance frequency.

Preferably, the loop gain of the oscillating circuit has two zeros at the highest impedance frequency.

Preferably, the starting oscillating frequency of the oscillating circuit is between the lowest impedance frequency and the highest impedance frequency.

Preferably, the oscillating frequency of the oscillating circuit is a frequency at which the phase difference is zero.

Preferably, the oscillating circuit comprises an amplifying element, a resistance and at least one capacitance.

Preferably, the amplifying element is an OP amplifier so as to increase the phase difference of the transducer.

To fulfill the aforementioned aim, the present invention further provides an ultrasonic transceiver system comprising: a frequency transmitter; and an ultrasonic transducer to which a signal with an operating frequency is transmitted from the frequency transmitter, the ultrasonic transducer having a lowest impedance frequency and a highest impedance frequency, and characterized in that the ultrasonic transceiver system further comprises an oscillating circuit having a loop gain whose maximum value occurs at the lowest impedance frequency of the transducer and whose minimum value occurs at the highest impedance frequency of the transducer, wherein a difference of a phase of the loop gain and an impedance phase of the transducer is zero between the lowest impedance frequency and the highest impedance frequency and the loop gain is of a value greater than 1 at a frequency where the phase difference is zero; and wherein the oscillating circuit is connected to the ultrasonic transducer to generate an oscillating frequency, which is the operating frequency.

Preferably, the ultrasonic transceiver system further comprises a shift unit for shifting between a first mode under which the oscillating circuit detects the operating frequency of the ultrasonic transducer and a second mode under which the frequency transmitter outputs a signal with the operating frequency to the ultrasonic transducer.

The oscillating device for frequency detection, ultrasonic transceiver system and frequency detection method thereof of the present invention may have one or more than one of the following advantages:

(1) The oscillating device for frequency detection, ultrasonic transceiver system and frequency detection method thereof can be used to detect whether or not an ultrasonic transducer meets the requirements on impedance during the quality control process. The best operating frequency for the ultrasonic transducer can be obtained by merely detecting the oscillating frequency.

(2) The oscillating device for frequency detection, ultrasonic transceiver system and frequency detection method thereof can provide online calibration function. As the best operating frequency for the ultrasonic transducer can be found through the oscillating circuit prior to the use of the ultrasonic transducer, the limitation in the manufacturing process will be reduced significantly. Therefore, the reception and transmission operation can be performed smoothly without culling products with variation. Moreover, the variation of the best operating frequency caused by changes in environment can be solved.

### BRIEF DESCRIPTION OF THE DRAWINGS

The exemplary embodiment(s) of the present invention will be understood more fully from the detailed description given below and from the accompanying drawings of various embodiments of the invention, which, however, should not be taken to limit the invention to the specific embodiments, but are for explanation and understanding only.

FIG. 1 is a circuit diagram illustrating the principle of an ultrasonic transducer.

FIG. 2 is a set of frequency response plots showing the impedance of the ultrasonic transducer measured by an impedance analyzer.

FIG. 3 is an operational equivalent circuit diagram of the ultrasonic transducer during power conversion.

FIG. 4 is an operational equivalent circuit diagram of the ultrasonic transducer during the reception operation.

FIG. 5 is a circuit diagram of an oscillating device for frequency detection in accordance with one embodiment of the present invention.

FIG. 6 is a small-signal equivalent circuit diagram of the embodiment of FIG. 5.

FIG. 7 illustrates the feedback gain of the small-signal equivalent circuit shown in FIG. 6.

FIG. 8 is a set of frequency response plots showing the impedance of the ultrasonic transducer and the loop gain of the oscillating circuit.

FIG. 9 is a set of frequency response plots showing the loop gain under the circumstance that the oscillating device for frequency detection is applied to an ultrasonic transducer.

FIG. 10 illustrates the oscillating frequency and impedance of the ultrasonic transducer measured under different temperatures.

FIG. 11 is a circuit diagram of an ultrasonic transceiver system in accordance with one embodiment of the present invention.

### DETAILED DESCRIPTION OF THE PREFERRED EMBODIMENTS

The present invention will be fully described by way of preferred embodiments and appended drawings to facilitate the understanding of the technical features, contents and advantages of the present invention. It will be understood that the appended drawings are merely schematic representations and may not represent actual scale and precise arrangement of the implemented invention. Therefore, the present invention shall not be construed based on the scale and arrangement illustrated on the appended drawings and the scope of protection thereof shall not be limited thereto.

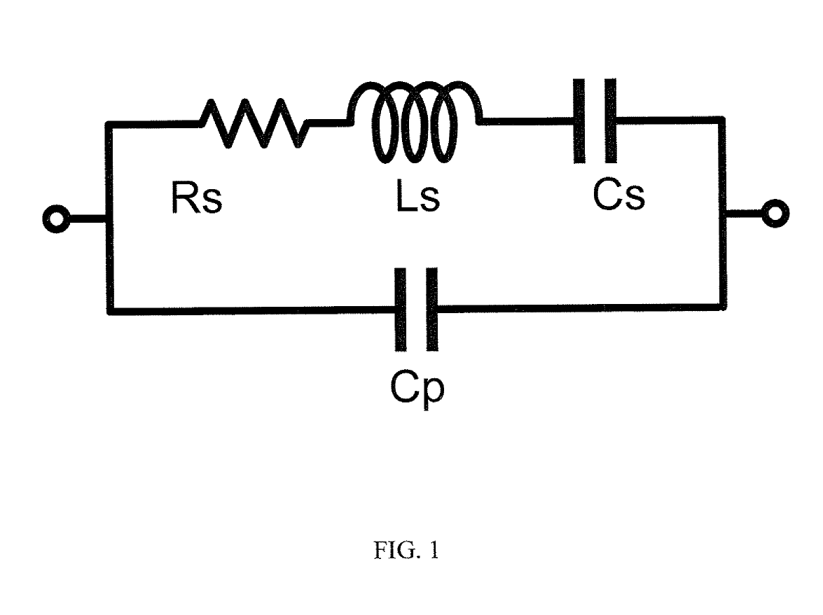

FIG. 1 is a circuit diagram illustrating the principle of an ultrasonic transducer. As shown in FIG. 1, the equivalent circuit model of the ultrasonic transducer is a circuit in which an inductance, a resistance and a capacitance are arranged in series and then arranged in parallel with a stray capacitance.

The resistance and its pole and zero positions can be derived from the component values of the equivalent circuit and expressed as follows:

$${Z}_{in} = \frac{1}{\frac{1}{s {L}_{s} + \frac{1}{s {C}_{s}} + {R}_{s}} + s {C}_{p}} = \frac{{s}^{2} {L}_{s} {C}_{s} + s {R}_{s} {C}_{s} + 1}{s ( {s}^{2} {L}_{s} {C}_{s} {C}_{p} + s {R}_{s} {C}_{s} {C}_{p} + {C}_{s} + {C}_{p} )}$$

$${ω}_{P 1} = 0 , {ω}_{P 2 , 3} = \sqrt{\frac{{C}_{s} + {C}_{p}}{{L}_{s} {C}_{s} {C}_{p}}} , \\ {ω}_{z 1 , 2} = \sqrt{\frac{1}{{L}_{s} {C}_{s}}}$$

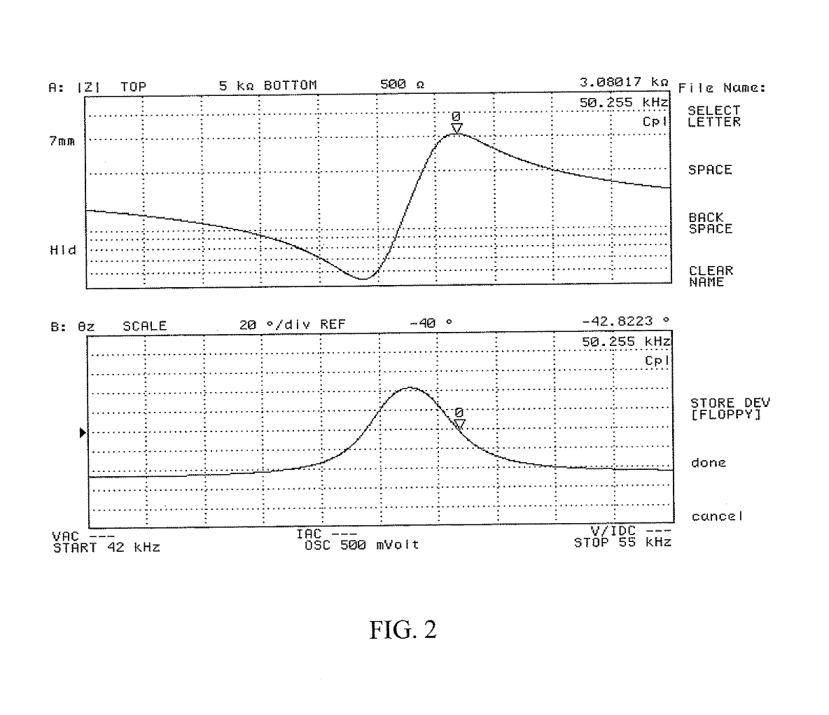

FIG. 2 is a set of frequency response plots showing the impedance of the ultrasonic transducer measured by an impedance analyzer. The plot on the top shows the impedance amplitude of the ultrasonic transducer measured by an impedance analyzer Angilent 4294A; the plot on the bottom shows the impedance phase of the ultrasonic transducer measured by the impedance analyzer Angilent 4294A. The frequency at the lowest point of the impedance amplitude is a frequency where the series resonance frequency corresponds to the impedance zero; the frequency at the highest point of the impedance amplitude is a frequency where the parallel resonance frequency corresponds to the impedance pole.

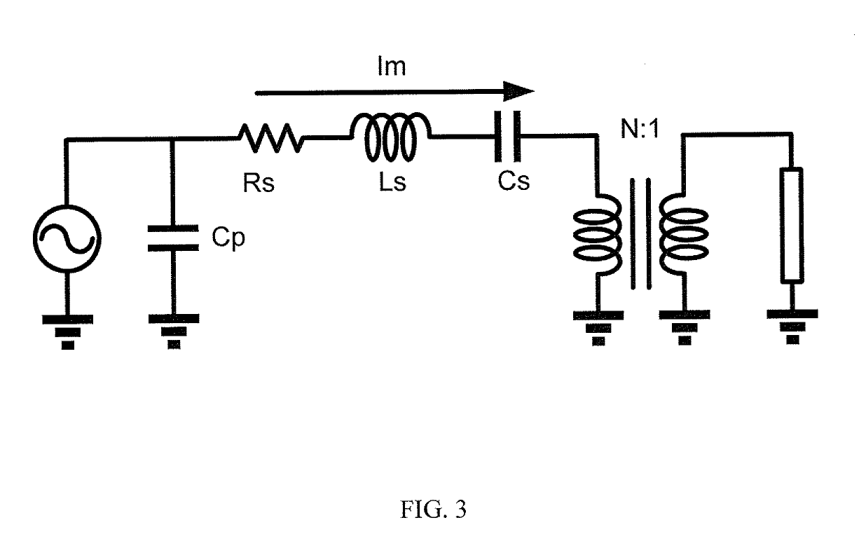

FIG. 3 is an operational equivalent circuit diagram of the ultrasonic transducer during power conversion. Referring to FIG. 3, an electricity equivalent model is illustrated on the left side of the transformer and a mechanics equivalent model is illustrated on the right side. A current supplied by the power source and flowing through the inductance, resistance, capacitance and transformer is referred to as a motional current, and the route along which the motional current flows is referred to as the motional path. In terms of circuitry, only currents flowing through the motional path can be converted to forces by the transformer, and the impedance on the right side is the load in mechanics. Referring to the equivalent model shown in FIG. 1, the ultrasonic transducer exerts a force acting directly upon the low load (aft). Therefore, the equivalent model shown in FIG. 3 can be simplified as the one shown in FIG. 1 when there is no cross voltage on the transformer.

After the operation of the equivalent circuit model of the ultrasonic transducer has been explicated above, the transmission and reception condition can be calculated. Regarding the transmission operation shown in FIG. 3, a voltage source is arranged at the left side to perform the transmission operation. The selected frequency must be able to maximize the motional current so as to maximize the transmission energy, thus the frequency at which the impedance of the motional path is minimum will be selected for the transmission operation. The impedance of the motional path is calculated as follows:

$${Z}_{m} = \frac{{s}^{2} {L}_{s} {C}_{s} + s {R}_{s} {C}_{s} + 1}{s {C}_{s}} , \\ ω {\vert}_{{z}_{m} , min} = \sqrt{\frac{1}{{L}_{s} {C}_{s}}}$$

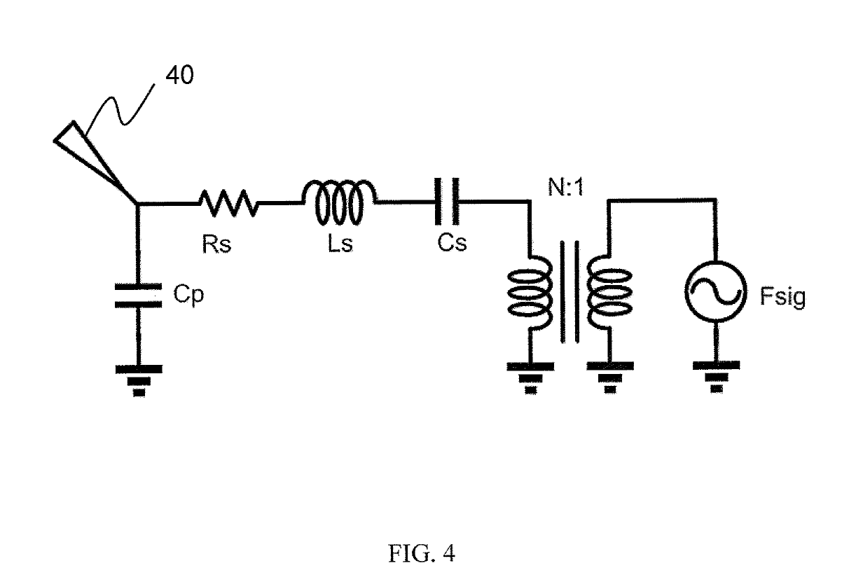

The calculation result shows that the minimum impedance value of the motional path is the same as the series resonance frequency. FIG. 4 is an operational equivalent circuit diagram of the ultrasonic transducer during the reception operation. As shown in FIG. 4, a voltage source is used to illustrate the vibration speed of the ultrasonic transducer, and a probe 40 is configured to receive voltages and perform the amplification operation.

The relation between the probe and the input voltage can be derived from FIG. 4 and expressed as follows:

$${V}_{probe} = {F}_{sig} \times N \times \frac{\frac{1}{s {C}_{p}}}{s {L}_{s} + \frac{1}{s {C}_{s}} + {R}_{s} + \frac{1}{s {C}_{p}}} = \frac{{F}_{sig} \times N}{{s}^{2} {L}_{s} {C}_{p} + s {R}_{s} {C}_{p} + \frac{{C}_{p}}{{C}_{s}} + 1}$$

It can be derived from the above equation that the maximum Vprobe occurs at

$$ω = \sqrt{\frac{{C}_{s} + {C}_{p}}{{L}_{s} {C}_{s} {C}_{p}}} ,$$

i.e. the parallel resonance frequency.

The best reception and transmission frequencies for the ultrasonic transducer are the series resonance frequency and the parallel resonance frequency of its impedance, respectively. Therefore, a frequency between the two frequencies is usually selected as the transmission frequency.

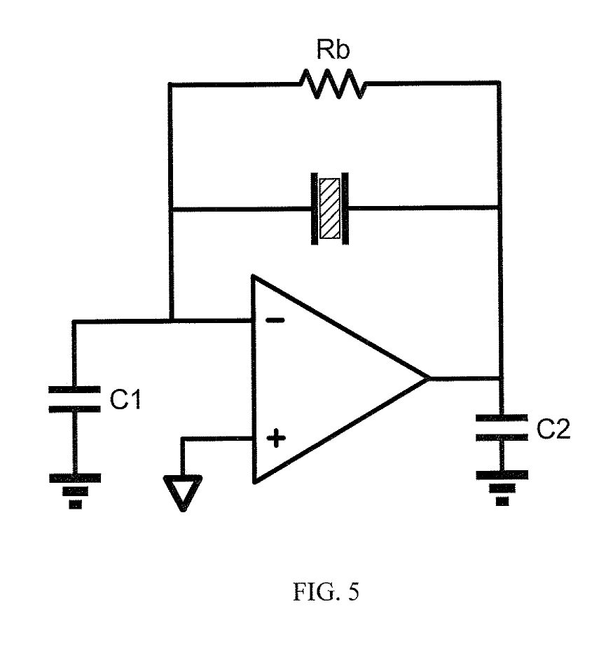

FIG. 5 is a circuit diagram of an oscillating device for frequency detection in accordance with one embodiment of the present invention. FIG. 5 illustrates an exemplary structure of the circuit of the present invention designed based on a crystal oscillator. The circuit comprises an OP amplifier TL082 with proper resistance, capacitance and ultrasonic transducer and exploits the phase variation of the ultrasonic transducer to oscillate. Next, a small-signal model will be used to analyze the feedback condition and the theoretical oscillating frequency of the circuit.

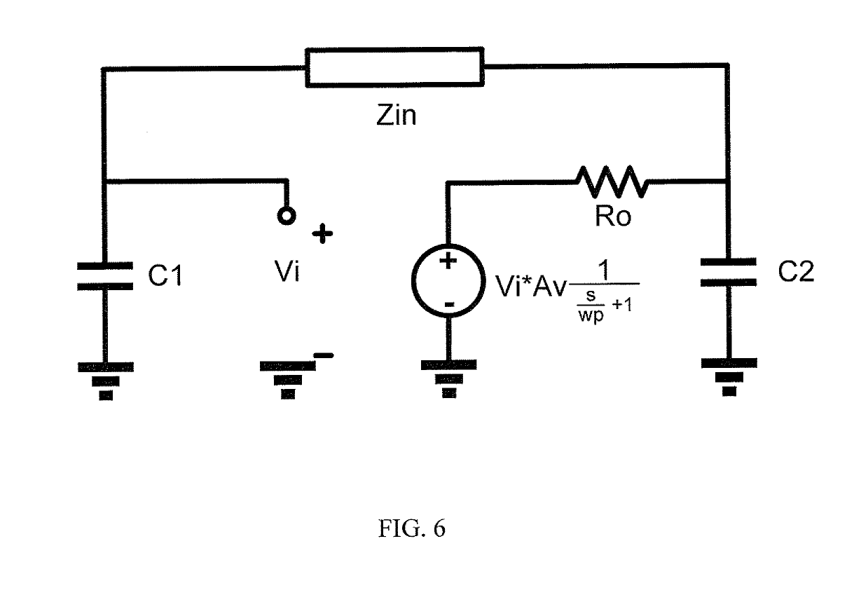

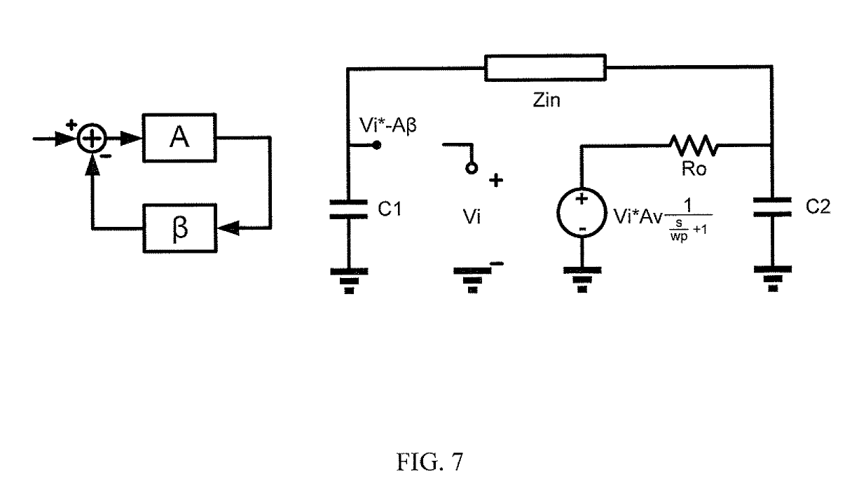

FIG. 6 is a small-signal equivalent circuit diagram of the embodiment of FIG. 5. As shown in FIG. 6, the OP amplifier can be simplified as a voltage control voltage source with an internal compensated pole, and the resistance and the ultrasonic transducer can be simplified as Zin. The feedback gain (Aβ) of the circuit can be calculated based on the feedback theory. Please also refer to FIG. 7 that illustrates the feedback gain of the small-signal equivalent circuit shown in FIG. 6. As shown in FIG. 7, −Aβ is calculated without taking into consideration the input end of the OP amplifier of the small-signal model. The circuit oscillates when the phase of −Aβ is 0 degree and the absolute value is greater than 1.

As Rb is configured to prevent the DC voltage of the OP amplifier from being overlooked during the operation process, its value can be set to be much greater than the impedance of the ultrasonic transducer. The maximum impedance amplitude of the ultrasonic transducer measured is around 5 k. Therefore, Rb is set to be 510 k Ohm. As the impedance of Rb is much greater than the impedance of the ultrasonic transducer, Zin can be regarded as having the impedance of the ultrasonic transducer only during the calculation, and the calculation is made taken into consideration the equivalent model shown in FIG. 1. The calculation result is provided as follows:

$$- A β = \frac{{A}_{v}}{( \frac{s}{{ω}_{p}} + 1 )} \frac{{C}_{p} {C}_{s} {L}_{s} {s}^{2} + {C}_{p} {C}_{s} {R}_{s} s + {C}_{p } + {C}_{s}}{denominator}$$

$$denominator = {R}_{o} {L}_{s} {C}_{s} ( {C}_{1} {C}_{2} + {C}_{1} {C}_{p} + {C}_{2} {C}_{p} ) {s}^{3} + [ {L}_{s} {C}_{s} ( {C}_{1} + {C}_{p} ) + {C}_{s} {R}_{o} {R}_{s} ( {C}_{1} {C}_{2} + {C}_{1} {C}_{p} + {C}_{2} {C}_{p} ) ] {s}^{2} + [ {R}_{o} ( {C}_{1} {C}_{2} + {C}_{1} {C}_{p} + {C}_{2} {C}_{p} + {C}_{s} ( {C}_{1} + {C}_{2} ) ) + {R}_{s} {C}_{s} ( {C}_{1} + {C}_{p} ) ] s + {C}_{1} + {C}_{p} + {C}_{s}$$

The zeros and poles of −Aβ are expressed as follows:

$${ω}_{z 1 , 2} = \sqrt{\frac{{C}_{s} + {C}_{p}}{{L}_{s} {C}_{s} {C}_{p}}} , \\ {ω}_{P 1} = {w}_{p} , {ω}_{p 2} \approx \frac{1}{{R}_{o} {C}_{2}} , \\ {ω}_{p 3 , 4} \approx \sqrt{\frac{1}{{L}_{s} {C}_{s}}}$$

As can be derived from the above equation, when the capacitance values of C1 and C2 are set to be greater than those of Cs and Cp, the zeros and poles of the impedance are as follows:

the zeros and poles of Zin:

$${ω}_{P 1} = 0 , {ω}_{P 2 , 3} = \sqrt{\frac{{C}_{s} + {C}_{p}}{{L}_{s} {C}_{s} {C}_{p}}} , \\ {ω}_{z 1 , 2} = \sqrt{\frac{1}{{L}_{s} {C}_{s}}}$$

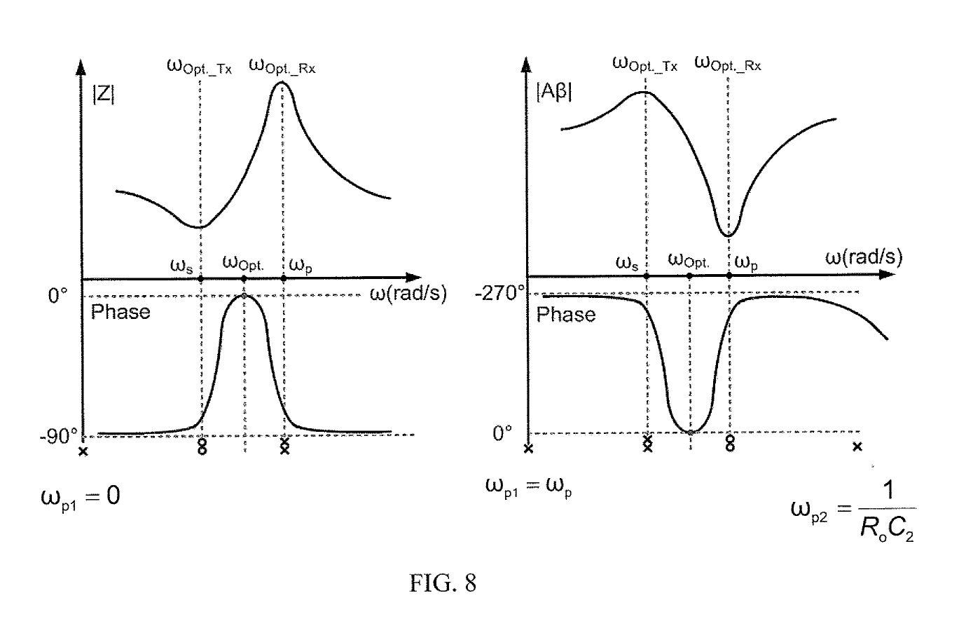

FIG. 8 is a set of frequency response plots showing the impedance of the ultrasonic transducer and the loop gain of the oscillating circuit. As shown in FIG. 8, the poles and zeros obtained from the calculation are marked on the frequency response plots. It can be seen from the comparison between the impedance and the loop gain that the measured phase difference is around 90 degrees as the impedance has a pole at 0, two zeros at the lowest impedance frequency and two poles at the highest impedance frequency. The loop gain of the oscillating circuit has a pole at the main pole of the amplifier, a pole at the output end of the amplifier, two poles at the frequency at the low point of the impedance and two zeros at the frequency at the high point of the impedance. That is, the relation between the poles and zeros of the loop gain and those of the impedance around the resonant frequency is reverse. It can be derived from the above description that −Aβ has a negative phase difference between the series resonance frequency and the parallel resonance frequency. If the phase difference provided by the transducer enables the loop gain of the oscillating circuit to exactly reach 0 degree and the gain is greater than 1, oscillation occurs.

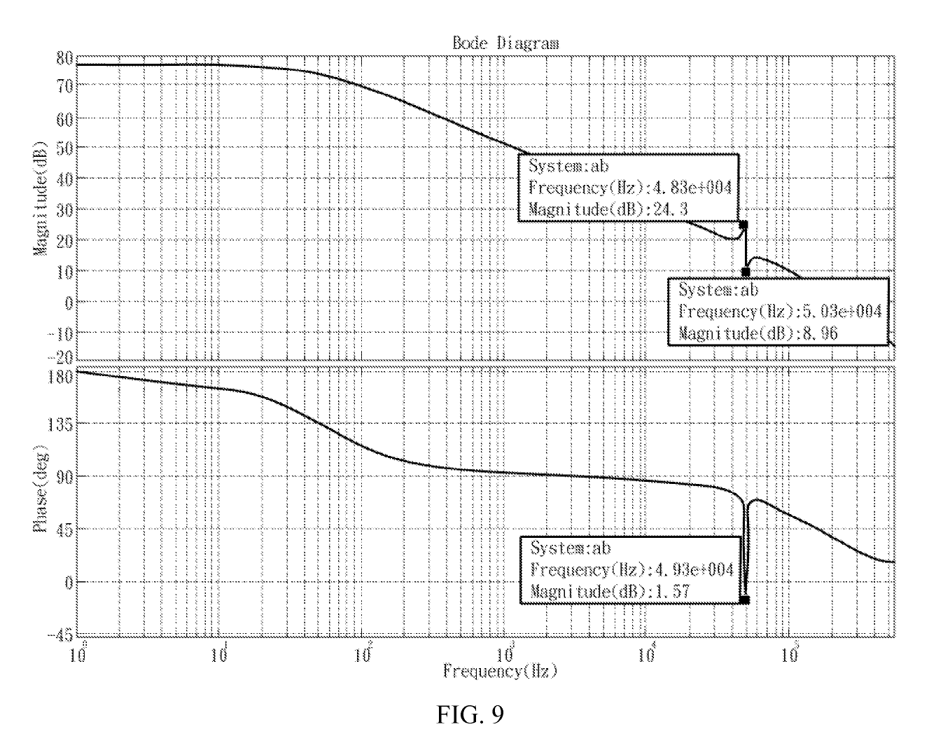

FIG. 9 is a set of frequency response plots showing the loop gain under the circumstance that the oscillating device for frequency detection is applied to an ultrasonic transducer. The frequency response plots are Bode plots drawn through the use of the Matlab that calculates the transfer function taking into consideration the bandwidth and output impedance of the OP amplifier TL082, the parameter of each component and the equivalent component values of the ultrasonic transducer.

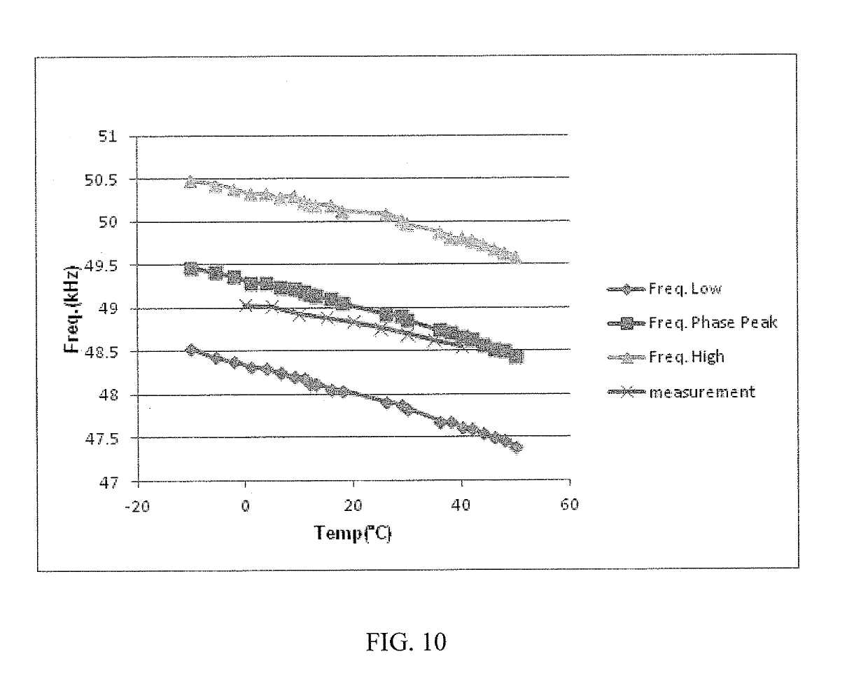

FIG. 10 illustrates the oscillating frequency and impedance of the ultrasonic transducer measured under different temperatures. As shown in FIG. 10, Fre.Low represents the series resonance frequency (the lowest impedance frequency) of the ultrasonic transducer, Fre.High represents the parallel resonance frequency (the highest impedance frequency), Fre.PhasePeak represents the highest frequency of the impedance phase, and measurement represents the oscillating frequency. It can be seen from the above experiment results that the series resonance frequency and the parallel resonance frequency of the impedance vary with the changes in the temperature of the ultrasonic transducer, and the best transmission point must be selected at a range of frequencies between the series resonance frequency and the parallel resonance frequency, i.e. the Fre.PhasePeak. It can be seen from the above experiment results that the oscillating frequency remains around the Fre.PhasePeak (within 1%) when varying with temperature changes.

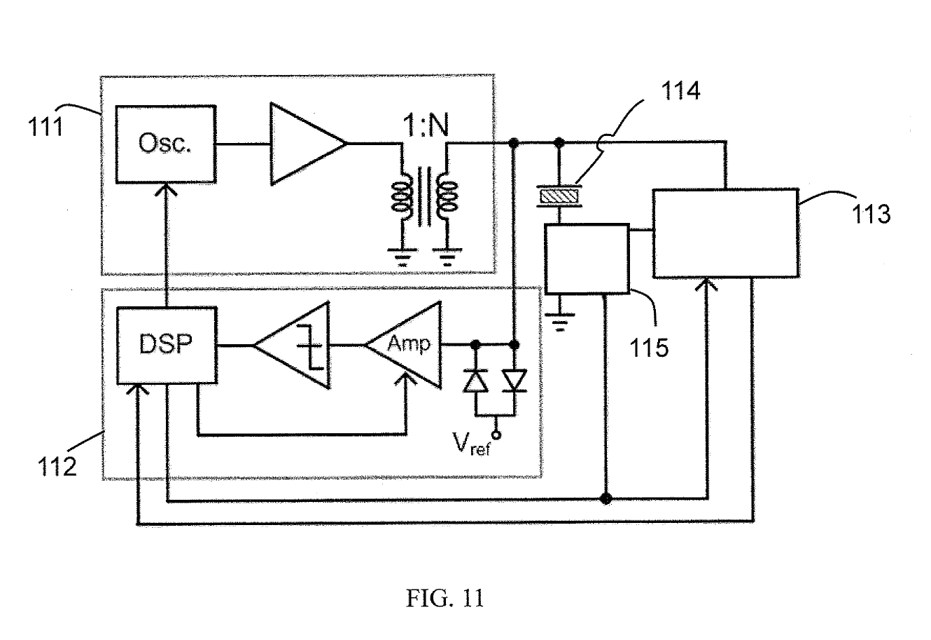

FIG. 11 is a circuit diagram of an ultrasonic transceiver system in accordance with one embodiment of the present invention. As shown in FIG. 11, when the oscillating frequency is selected as the most appropriate transmission frequency for the ultrasonic transducer 114, an oscillating device for frequency detection 113 can be used to find the best reception and transmission frequencies, i.e. the operating frequencies between the series resonance frequency and the parallel resonance frequency. Next, the best reception and transmission frequencies found are transmitted to the receiving circuit block 112 of the frequency transmitter. The frequency transmitter then outputs a signal with the best reception and transmission frequencies to the ultrasonic transducer 114 through the transmitting circuit block 111.

In conclusion, the oscillating device for frequency detection, ultrasonic transceiver system and frequency detection method of the present invention can exploit the impedance of the ultrasonic transducer to make selection. Generally speaking, as the transmission operation performed at a frequency where the impedance is the lowest, i.e. the series resonance frequency, under a fixed voltage requires the maximum power consumption, such a frequency is the best transmission frequency for the ultrasonic transducer. The best reception frequency for the ultrasonic transducer is the parallel resonance frequency because the highest impedance of the ultrasonic transducer occurs when reception operation is performed at the frequency, thereby acquiring the highest reception voltage. The present invention introduces the above phase shift to the structure of a crystal oscillator so that the crystal oscillator oscillates after a positive feedback is formed between the series resonance frequency and the parallel resonance frequency and determines the reception and transmission frequencies based on the oscillating frequency.

The embodiments depicted above and the appended drawings are exemplary and are not intended to limit the scope of the present creation. Any change or alteration with equivalent efficiency made without departing from the spirit and scope of this invention fall within the scope of the appended claims.

What is claimed is:

1. An oscillating device for frequency detection for detecting a transducer having a lowest impedance frequency and a highest impedance frequency, comprising:
an oscillating circuit having a loop gain whose maximum value occurs at the lowest impedance frequency of the transducer and whose minimum value occurs at the highest impedance frequency of the transducer, wherein a difference of a phase of the loop gain and an impedance phase of the transducer is zero between the lowest impedance frequency and the highest impedance frequency and the loop gain is of a value greater than 1 at a frequency where the phase difference is zero.

2. The oscillating device for frequency detection according to claim 1, wherein the transducer is an ultrasonic transducer and the lowest impedance frequency is the best transmission frequency for the ultrasonic transducer.

3. The oscillating device for frequency detection according to claim 2, wherein the ultrasonic transducer has two zeros at the lowest impedance frequency.

4. The oscillating device for frequency detection according to claim 1, wherein the loop gain of the oscillating circuit has two poles at the lowest impedance frequency.

5. The oscillating device for frequency detection according to claim 1, wherein the transducer is an ultrasonic transducer and the highest impedance frequency is the best reception frequency for the ultrasonic transducer.

6. The oscillating device for frequency detection according to claim 5, wherein the ultrasonic transducer has two poles at the highest impedance frequency.

7. The oscillating device for frequency detection according to claim 1, wherein the loop gain of the oscillating circuit has two zeros at the highest impedance frequency.

8. The oscillating device for frequency detection according to claim 1, wherein a starting oscillating frequency of the oscillating circuit is between the lowest impedance frequency and the highest impedance frequency.

9. The oscillating device for frequency detection according to claim 1, wherein an oscillating frequency of the oscillating circuit is a frequency at which the phase difference is zero.

10. The oscillating device for frequency detection according to claim 1, wherein the oscillating circuit comprises an amplifying element, a resistance and at least one capacitance.

11. The oscillating device for frequency detection according to claim 10, wherein the amplifying element is an OP amplifier so as to increase the phase difference of the transducer.

12. An ultrasonic transceiver system comprising: a frequency transmitter; and an ultrasonic transducer to which a signal with an operating frequency is transmitted from the frequency transmitter, the ultrasonic transducer having a lowest impedance frequency and a highest impedance frequency, and characterized in that
the ultrasonic transceiver system further comprises an oscillating circuit having a loop gain whose maximum value occurs at the lowest impedance frequency of the transducer and whose minimum value occurs at the highest impedance frequency of the transducer, wherein a difference of a phase of the loop gain and an impedance phase of the transducer is zero between the lowest impedance frequency and the highest impedance frequency and the loop gain is of a value greater than 1 at a frequency where the phase difference is zero; and wherein the oscillating circuit is connected to the ultrasonic transducer to generate an oscillating frequency, which is the operating frequency.

13. The ultrasonic transceiver system according to claim 12 further comprising a shift unit for shifting between a first mode under which the oscillating circuit detects the operating frequency of the ultrasonic transducer and a second mode under which the frequency transmitter outputs a signal with the operating frequency to the ultrasonic transducer.

14. A frequency detection method for detecting an operating frequency of a transducer having a lowest impedance frequency and a highest impedance frequency, comprising:
providing an oscillating circuit having a loop gain and an output end, a maximum value of the loop gain occurring at the lowest impedance frequency of the transducer, a minimum value of the loop gain occurring at the highest impedance frequency of the transducer, a difference of a phase of the loop gain and an impedance phase of the transducer being zero between the lowest impedance frequency and the highest impedance frequency and the loop gain being of a value greater than 1;
connecting the transducer to the output end of the oscillating circuit; and
measuring an oscillating frequency of the oscillating circuit, the oscillating frequency being the operating frequency of the transducer.

15. The frequency detection method according to claim 14, wherein the transducer is an ultrasonic transducer and the lowest impedance frequency is the best transmission frequency for the ultrasonic transducer.

16. The frequency detection method according to claim 15, wherein the ultrasonic transducer has two zeros at the lowest impedance frequency.

17. The frequency detection method according to claim 14, wherein the loop gain of the oscillating circuit has two poles at the lowest impedance frequency.

18. The frequency detection method according to claim 14, wherein the transducer is an ultrasonic transducer and the highest impedance frequency is the best reception frequency for the ultrasonic transducer.

19. The frequency detection method according to claim 18, wherein the ultrasonic transducer has two poles at the highest impedance frequency.

20. The frequency detection method according to claim 14, wherein the loop gain of the oscillating circuit has two zeros at the highest impedance frequency.

21. The frequency detection method according to claim 14, wherein a starting oscillating frequency of the oscillating circuit is between the lowest impedance frequency and the highest impedance frequency.

22. The frequency detection method according to claim 14, wherein the oscillating frequency of the oscillating circuit is a frequency at which the phase difference is zero.

23. The frequency detection method according to claim 14, wherein the oscillating circuit comprises an amplifying element, a resistance and at least one capacitance.

24. The frequency detection method according to claim 23, wherein the amplifying element is an OP amplifier so as to increase the phase difference of the transducer.
